(19) United States
(12) Patent Application Publication
(10) Pub. No.: US 2016/0218734 A1
(43) Pub. Date: Jul. 28, 2016

(54) DUAL THRESHOLD AUTOMATIC GAIN CONTROL SYSTEM AND METHOD

(71) Applicant: Avago Technologies General IP (Singapore) Pte. Ltd., Singapore (SG)

(72) Inventors: Amaresh V. Malipatil, San Jose, CA (US); Viswanath Annampedu, Schnecksville, PA (US)

(21) Appl. No.: 14/604,336

(22) Filed: Jan. 23, 2015

(51) Int. Cl. H03M 1/18; H04B 1/16

(52) U.S. Cl. CPC H03M 1/183; H04B 1/16

(57) ABSTRACT

A system, method, and Serializer/Deserializer (SerDes) channel are provided that include an automatic gain control module and method of operating the same. The automatic gain control module is provided with a digital feedback signal and includes a first accumulator and second accumulator that compare the digital feedback signal against thresholds. Based on counts made by the accumulators, a variable gain amplifier may have its gain adjusted.

### FIELD OF THE DISCLOSURE

The present disclosure is generally directed toward an analog-to-digital converter and automatic gain control for the same.

### BACKGROUND

Automatic Gain Control (AGC) refers to a process of automatically adjusting the gain of a signal-receiving component in a communication system. AGC is a closed-loop circuit, the purpose of which is to provide a controlled signal amplitude at its output, despite changes in amplitude at the input signal. In traditional AGC circuits, the average or peak output signal level is used to dynamically adjust the input-to-output gain to a desirable value, thereby enabling the receiving component to operate appropriately across a range of input signal levels. In other words, most AGC circuits attempt to maintain a constant signal level at the output, regardless of the signal's variation at the input of the system.

### BRIEF DESCRIPTION OF THE DRAWINGS

The present disclosure is described in conjunction with the appended figures, which are not necessarily drawn to scale:

FIG. 1 is a block diagram depicting a communication system in accordance with embodiments of the present disclosure;

FIG. 2 is a block diagram depicting details of a receiver in accordance with embodiments of the present disclosure;

FIG. 3 depicts an analog-to-digital converter's output as a function of time;

FIG. 4 is a flow diagram depicting a method of implementing a dual threshold AGC in accordance with embodiments of the present disclosure; and

FIG. 5 is a flow diagram depicting a method of limiting corrections in an AGC circuit in accordance with embodiments of the present disclosure.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

Various aspects of the present disclosure will be described herein with reference to drawings that are schematic illustrations of idealized configurations. As such, variations from the shapes of the illustrations as a result, for example, manufacturing techniques and/or tolerances, are to be expected. Thus, the various aspects of the present disclosure presented throughout this document should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

While embodiments of the present disclosure will be described in connection with a receiver in a particular type of mixed signal communication system, it should be appreciated that embodiments of the present disclosure are not so limited. In particular, the concepts of a dual threshold ACG system and method described herein can be utilized in a wide variety of systems that utilize both analog and digital signal processing. While the particular type of low-level circuit described herein (e.g., a Serializer/Deserializer (SerDes)) is capable of utilizing the dual threshold AGC system and method, other types of receivers or mixed signal communication system components can also benefit from the concepts described herein. Any type of Integrated Circuit (IC), IC chip, IC chip component, radar, audio/video signal processing, telephone system, etc. can utilize the dual algorithm AGC systems and methods described herein.

Accordingly, a dual threshold AGC system and method are disclosed. The AGC system and method causes the sampled analog signal at an Analog-to-Digital Converter (ADC) input to occupy close to its full dynamic range (e.g., input range supported by the ADC) by adjusting a Variable Gain Amplifier (VGA). If the input to the ADC occupies its full dynamic range, then the quality of the digital samples produced at the ADC output will be better because the ADC can resolve its input better into multiple quantization levels that it can support. For example, if the ADC input amplitude is very small, then most of the digital sample values will be close to 0. Whereas, if the ADC input spans a wide range, then the digital samples will also span a wide range by fully utilizing all quantization levels of the ADC. Also, by doing so, the effect of unwanted electrical noise will also be reduced when the incoming signal amplitude is larger. While maximization of the ADC input is desirable, there are also problems associated with oversaturation of the signal. For instance, when the input amplitude exceeds the dynamic range of the ADC, the ADC will produce samples with constant values corresponding to the largest value that the ADC can deliver. Saturation causes issues in data detection and in the settling behavior of adaptive loops in the system as the saturated ADC samples do not represent the true value of the input analog signal. Thus, it is desirable to operate the AGC system and method such that the maximum of the ADC input lies closer to the dynamic range of the ADC without oversaturation.

Embodiments of the present disclosure also solve the problem associated with whenever AGC changes, so too does the gain of the VGA. In a complex system involving multiple adaptive loops, any change in the signal path gain requires some amount of time for the complex interaction between multiple adaptive loops to settle out. Thus, embodiments of the present disclosure cause the AGC to react less frequently, thereby allowing the adaptive loops to settle out.

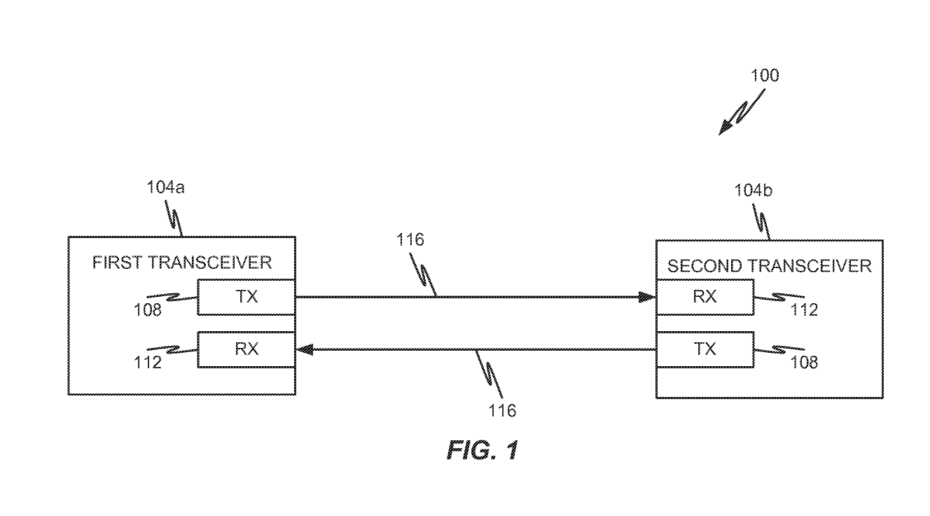

Referring now to FIG. 1, a mixed signal communication system 100 will be described in accordance with at least some embodiments of the present disclosure. The system 100 is shown to include one or more transceivers 104a, 104b, each having a transmitter 108 and a receiver 112. The transceivers 104a, 104b are shown to communicate with one another via one or more communication channels 116 that connect a transmitter 108 with a receiver 112. It should be appreciated that embodiments of the present disclosure may also be implemented in a communication system having dedicated transmitters 108 and receivers 112 instead of a combination of a transmitter 108 and receiver 112 being implemented in a transceiver 104.

In some embodiments, the communication channel 116 may carry an analog signal that is modulated according to any type of known modulation technique, such as Amplitude Modulation, Double-Sideband Modulation, Vestigal Sideband Modulation, Quadrature Amplitude Modulation, Frequency Modulation, Phase Modulation, combinations thereof, or the like. The communication channel 116 may include a wired communication medium (e.g., a physical wire, coaxial cable, fiber-optics, etc.), a wireless communication medium (e.g., air), or a combination of wired and wireless media. It should be appreciated that the transmitter 108 may be configured to first receive a digital signal as an input (e.g., from a digital circuit or digital circuit components, such as an IC or IC component) and then convert the digital signal into an analog signal for transmission across the communication channel 116. The receiver 112 may be configured to receive the analog signal from the communication channel 116 and convert the analog signal back into a digital signal for processing by a digital circuit that is connected to an output of the receiver 108. It should be appreciated that the communication channel 116 may traverse long or short distances. For instance, the communication channel 116 may correspond to a short interconnection between components on an IC chip. In some embodiments, the communication channel 116 may correspond to a SerDes channel. As another example, the communication channel 116 may correspond to a long interconnection (e.g., on the order of miles) between a transmitting station and a receiving station.

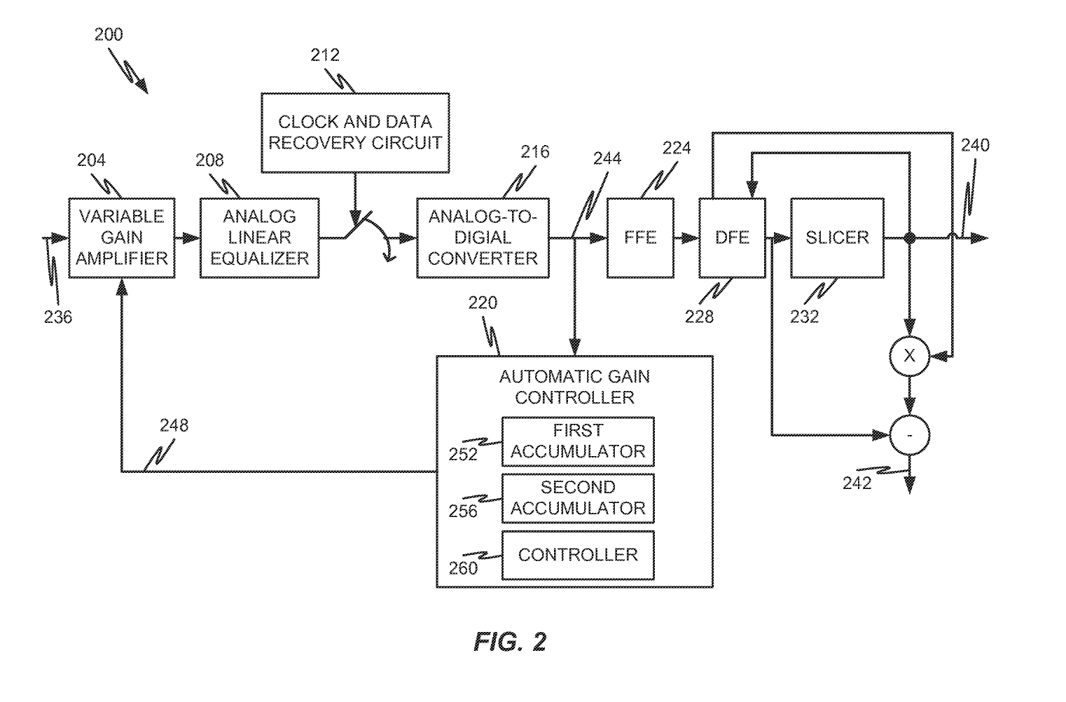

FIG. 2 shows additional details of a receiver 200 in accordance with embodiments of the present disclosure. The receiver 200 may correspond to receiver 108, a component of receiver 108, or the like. In the depicted embodiment, the receiver 200 receives an input signal 236, which may correspond to a signal transmitted by a transmitter 108 over the communication channel 116 or to some other type of input signal. In some embodiments, the input signal 236 may correspond to an analog signal that is carrying information vis-à-vis modulation of the analog signal. The receiver 200 may provide the ability to convert the analog input signal 236 into a digital output signal 240 that is capable of being processed by a digital circuit or digital circuit components. In some embodiments, the receiver 200 may comprise multiple components that enable an efficient and useful conversion of the analog signal to a digital signal.

In the depicted embodiment, the receiver 200 comprises a VGA 204, an analog linear equalizer 208, a clock and data recovery circuit 212, an ADC 216, an automatic gain controller 220, a Feed Forward Equalizer (FFE) 224, a Decision Feedback Equalizer (DFE) 228, and a slicer 232. The VGA 204 is positioned at the front of the receiver 200 and directly receives the input signal 236. The VGA 204 may be configured to amplify the received input and provide the amplified analog signal to the analog linear equalizer 208. The analog linear equalizer 208 may be configured to equalize the amplified analog signal received from the VGA 204. Any type of equalizer or combination of equalizing components may be utilized to implement the analog linear equalizer 208. Functionally, the analog linear equalizer 208 may be configured to process the received signal with one or more linear filters to minimize the error signal prior to further processing.

The analog linear equalizer 208 may then selectively provide the equalized analog signal to the ADC 216. The timing with which the signal is provided to the ADC may be controlled by a switchable interconnection that is actuated by the clock and data recovery circuit 212. In some embodiments, the switchable interconnection between the analog linear equalizer 208 and ADC 216 may be normally connected or normally disconnected and the clock and data recovery circuit 212 may provide control signals to the switchable interconnection to move the interconnection between a connected and disconnected state. The clock and data recovery circuit 212 may operate in a known fashion, for example the clock and data recovery circuit 212 may be used to generate a clock from an approximate frequency reference and then phase-align to the transitions in the input signal 236 with a phase-locked loop.

The ADC 216 may comprise one or more components that convert the analog signal received from the analog linear equalizer 208 into a digital signal. Any type of known converting circuit or combination of circuit components may be used within the ADC 216. As an example, the ADC 216 may comprise the ability to convert a continuous physical quantity in the analog signal (e.g., voltage) to a digital number that represents the quantity's amplitude. The ADC 216 may sample the input periodically to produce the digital output 244. As will be discussed in further detail herein, the digital output 244 of the ADC 216 may be provided directly to an automatic gain controller 220 as well as the FFE 224.

With respect to the FFE 224, the digital signal 244 may be processed in an attempt to reverse the distortion incurred by a signal transmitted through the channel 116. In some embodiments, the FFE 224 may be configured to correct the received waveform with information about the waveform itself and not information made on the waveform. The FFE 224 may behave like a Finite Impulse Response (FIR) filter that uses the voltage levels of the received waveform associated with previous and current bits to correct the voltage level of the current bit.

Output of the FFE 224 is then provided to the DFE 228, which may be implemented in a number of different ways. In some embodiments, the DFE 228 may calculate a correction value based on feedback inputs (e.g., inputs received from an output of slicer 232) that is added to the logical decision threshold (e.g., the threshold above which the waveform is considered a logical high or ‘1’ and below which the waveform is considered a logical low or ‘0’).

The output of the DFE 228 may then be provided simultaneously to the slicer 232 and a comparator. The slicer 232 may process the input received from the DFE 228 by slicing the signal into smaller bit widths. For example, each component of the slicer 232 may process one bit field or slice of an operand. The components of the slicer 232 may then have the capability to process the chosen full word-length of a particular software design. In some embodiments, the slicer output corresponds to digital output signal 240, which can be provided to other digital circuit components, such as an IC chip or the like. The digital data is also provided as an input to the DFE 228 thereby assisting the DFE 228 in creating a DFE target value. The DFE target value determined by the DFE 228 may be provided as output to a multiplier operand for combining with the digital data 240. The output of the multiplier operand may then be provided to a comparator, which compares the output with the output from the DFE 228, thereby generating an error signal 242. The error signal 242 can be used for one or more adaptive loops in the SerDes channel.

Referring back to the automatic gain controller 220, the digital output 224 of the ADC 216 is shown to be provided directly to the automatic gain controller 220. It should be appreciated, however, that the automatic gain controller 220 may receive its input from any portion of the circuit after the ADC 216. For instance, the automatic gain controller 220 may receive its input from the FFE 224, the DFE 228, the slicer 232, or from some other digital-processing component of the circuit 200.

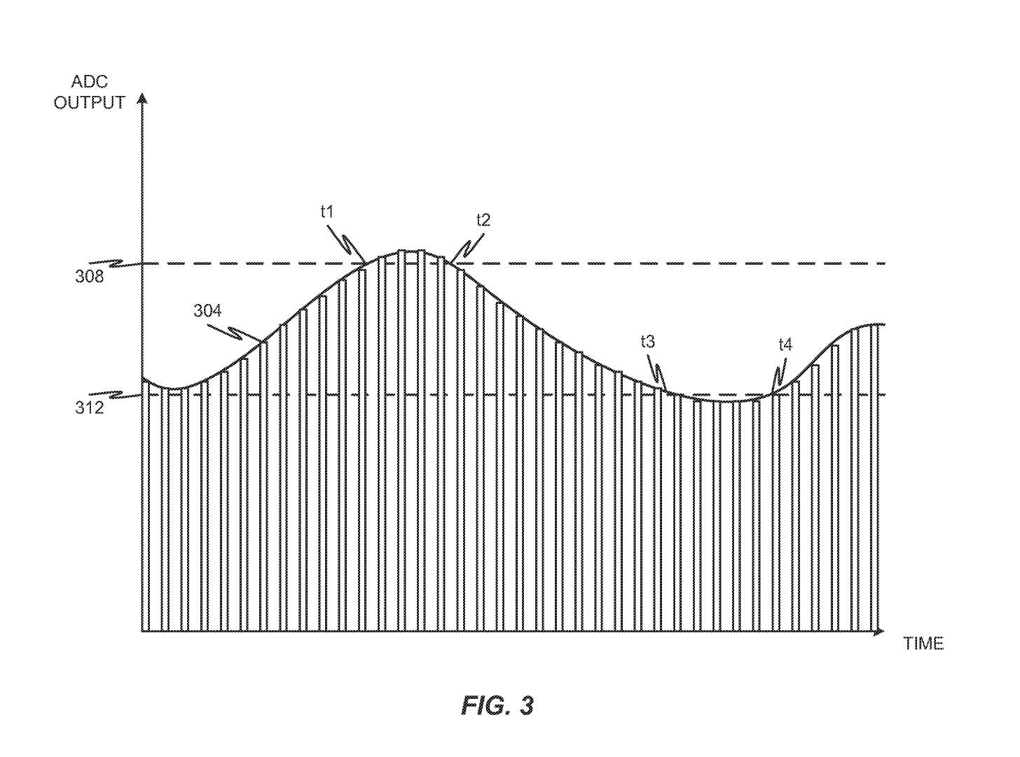

The automatic gain controller 220 is shown to include a first accumulator 252 and a second accumulator 256 as well as a controller 260. The controller 260 may be implemented as a digital logic circuit, firmware, software, or some combination thereof. The controller 260 may utilize the first and second accumulators 252, 256 to determine whether and to what extent the VGA 204 should be adjusted or incremented. In some embodiments, the automatic gain controller 220 controls the VGA 204 with a control signal 248 that is adjusted by the controller 260. In particular, and with reference to FIG. 3, the VGA 204 may utilize the controller 260 to ensure that the output of the ADC 244 (shown as output 304 in FIG. 3) is within a preferred operation window between an upper threshold 308 and a lower threshold 312. If the ADC output 244, 304 exceeds the upper threshold 308 (e.g., between time t1 and t2), then the controller 260 adjusts the VGA 204 to amplify the analog signal 236 less, thereby decreasing the ADC output 244, 304. Likewise, if the ADC output 244, 304 falls below the lower threshold 312 (e.g., between time t3 and t4), then the controller 260 adjusts the VGA 204 to amplify the analog signal 236 more, thereby increasing the ADC output 244. The goal of the controller 260 is to ensure that maximum of the ADC 216 input lies closer to the dynamic range of the ADC without over-saturating the ADC 216.

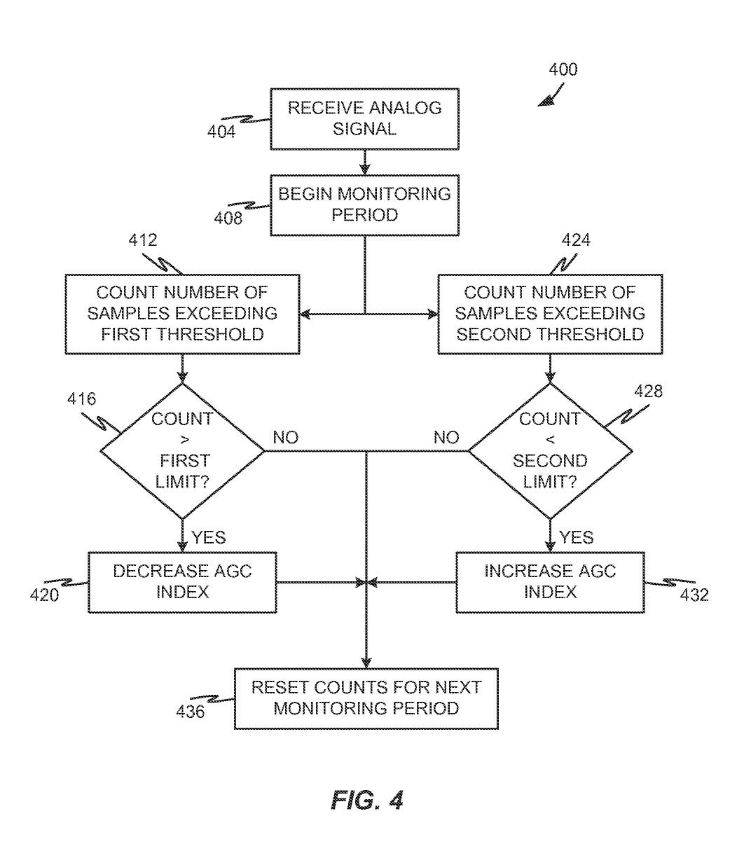

With reference now to FIG. 4, additional details of the automatic gain controller 220 and its functionality will be described in accordance with at least some embodiments of the present disclosure. FIG. 4 depicts a method 400 of operating a dual-threshold AGC in accordance with embodiments of the present disclosure. The method 400 begins when an analog signal 236 is received at the receiver 200 (step 404). The method 400 continues with the controller 260 beginning a monitoring period (step 408). In some embodiments, the monitoring period and the length/duration thereof may be defined in terms of time (e.g., a predetermined amount of time will pass until the monitoring period is complete). In some embodiments, the monitoring period and the length/duration thereof may be defined in terms of symbol intervals and/or clock cycles (e.g., a predetermined number of symbols and/or clock cycles will occur until the monitoring period is complete). Any other event or combinations of events or conditions may be used to define the beginning and or end of the monitoring period without departing from the scope of the present disclosure.

The method 400 proceeds by implementing both the first accumulator 252 and second accumulator 256 in parallel during the monitoring period. With respect to the first accumulator 252, the first accumulator 252 counts the number of samples in the digital signal 244, 304 that exceed the first threshold 308 (step 412). In the example of FIG. 3, four samples are shown to exceed the first threshold 308 between time t2 and t2. Although the waveform depicted in FIG. 3 is shown to be across time, it should also be appreciated that samples may be compared and accumulated per clock cycle or per symbol interval without departing from the scope of the present disclosure. As the first accumulator 252 counts the number of samples exceeding the first threshold 308 during the monitoring period, each such instance where another sample is added to the count (e.g., when a sample is determined to exceed the first threshold 308), the total count for the monitoring period is incremented. In other words, the first accumulator 252 sums all instances of samples that exceed the first threshold 308 during the monitoring period. If a sample does not exceed the first threshold 308, then the first accumulator 252 will not increment its running sum. At the end of the monitoring period the method continues with the controller 260 determining whether the count or sum developed by the first accumulator 252 exceeds a first predetermined limit (step 416). In particular, the controller 260 may compare an output of the first accumulator 252 after the monitoring period has ended with an upper programmable sum limit. If the count/summation of the first accumulator 252 does not exceed the first predetermined limit, then the method proceeds by resetting the count of the first accumulator 252 and waiting for the next monitoring period (step 436).

If, however, the count of the first accumulator 252 exceeds the first predetermined limit, then the controller 260 will decrease the AGC index (e.g., by an incremental vale of one decibel) by adjusting the gain of the VGA 204 (step 420). Thereafter, the method 400 proceeds to step 436.

In parallel with processing of the first accumulator 252 output, the second accumulator 256 counts the number of samples exceeding the second threshold 312 (step 424). In the example of FIG. 3, every sample with the exception of the five samples between time t3 and t4 is counted and summed by the second accumulator 256. The output of the second accumulator 256 is then compared with a second limit to determine if the AGC index should be decreased (step 428). Specifically, if the count of the second accumulator 256 along the monitoring period fails to exceed the lower programmable sum limit, then the AGC index is increased to bring the ADC output closer to the peak of its dynamic range (step 432). Thereafter, or in the event that the count of the second accumulator 256 exceeds the lower programmable sum limit, the method 400 proceeds to step 436.

In a more specific example, the first threshold may correspond to a value that is approximately 1 dB below the peak of the ADC's 216 capabilities and the second threshold may correspond to a value that is approximately 1 dB below the first threshold. The first accumulator 252 may accumulate (absolute sum) the number of ADC output samples that are over the first threshold 308 (e.g., 27 LSBs for a 6 bit ADC) over the programmable monitoring period. The second accumulator 256 may accumulate the number of ADC output samples that are over the second threshold 312 (e.g., 24 LSBs for a 6 bit ADC) over the programmable monitoring period (or a different period). In some embodiments, the programmable monitoring period may be several thousands of symbol intervals to average out noise and other signal anomalies. When the number of samples that are above the upper level (e.g., 27 LSBs) exceeds a programmable upper limit (e.g., 4 symbols), the VGA index will be decremented by the controller 260 to decrease the signal path gain. When the number of samples that do not exceed the second threshold 312 (e.g., 24 LSBs) does not exceed another programmable limit (e.g., 4 symbols or some other value different from the programmable upper limit), the VGA index will be incremented to increase the signal path gain. This will prevent the AGC index from toggling under normal conditions and will react to Process Voltage Temperature (PVT) changes as needed in a stable manner

It should be noted that the example of ADC 216 outputs of 27 LSBs and 24 LSBs are about 1 dB apart. When the ADC 216 input is within this range, the controller 260 will not change the VGA index and hence doesn't disturb the adaptive loops. Moreover, by utilizing the full dynamic range of the ADC 216, the receiver 200 will be able to operate in a more efficient and accurate manner.

It should be appreciated that the example of FIG. 3 may correspond to the depiction of a single monitoring period or multiple monitoring periods. The depiction of samples falling above and below the preferred operational window (e.g., above the first threshold and below the second threshold) during a single monitoring period is unlikely but not impossible. Instead, a first monitoring period may occur from the first sample taken until some time after the second time t2 and before the third time t3. After detecting multiple samples above the first threshold 308, the controller 260 may adjust the gain of the VGA 204, thereby causing the signal 244, 304 to fall below the second threshold 312. Thus, the second monitoring period may have begun before the third time t3 but ended after the fourth time t4.

As can be appreciated, the first and second accumulator 252, 256 may count samples or conditions other than those depicted in FIG. 4. The purpose of the accumulators 252, 256 is to compare the samples to an optimal operational window that resides between the first threshold 308 and second threshold 312. In some embodiments, the first accumulator 252 may count the number of samples below the first threshold 308 and the second accumulator 256 may count the number of samples below the second threshold 312. Based on the events that are being counted by the accumulators 252, 256 the behavior of the controller 260 may be modified. In other words, embodiments of the present disclosure are not limited to counting samples above first and second thresholds to determine of the ADC 216 is operating in an optimal range.

Likewise, the first and second accumulators 252, 256 may operate along different monitoring periods. For instance, the first accumulator 252 may operate along a first monitoring period that is different (e.g., shorter or longer in duration, number of clock cycles, number of symbol intervals, etc.) from the monitoring period that the second accumulator 256 operates along. Thus, while it may be useful to have the first and second accumulators 252, 256 operate along the same monitoring period, such a constraint is not imposed on embodiments of the present disclosure.

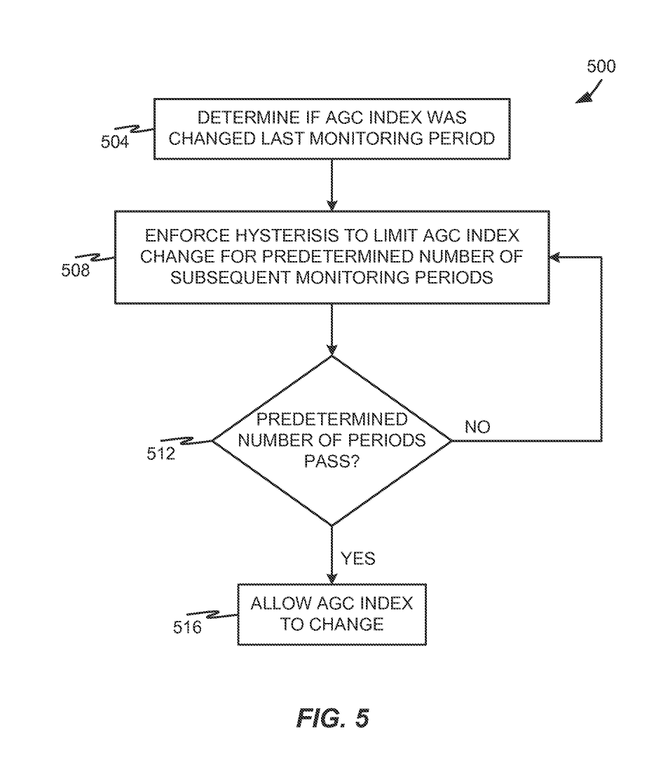

With reference now to FIG. 5, a method 500 of limiting the controller 260 overreaction to changes in the ADC 216 output will be described in accordance with embodiments of the present disclosure. The method 500 begins when it is determined that the AGC index was changed during a last monitoring period (step 504). In response to making such a determination, the controller 260 may enforce hysteresis or a resistance to changing the AGC index for a predetermined number (e.g., one, two, three, etc.) of subsequent monitoring periods (step 508). After the predetermined number of monitoring periods have passed (step 512), then the controller 260 allows itself to begin changing the AGC index again (step 516). By enforcing this type of condition, the controller 260 does not continuously change the AGC index at the VGA 204, thereby allowing adaptive loops to react to a previous change before subsequent changes are made by the controller 260.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

1. A Serializer/Deserializer (SerDes) channel, comprising:
an input that receives an input analog signal;
an output that provides a digital output signal corresponding to the analog input signal;
a variable gain amplifier positioned between the input and output;
an analog-to-digital converter receiving an input from the variable gain amplifier; and
an automatic gain control module receiving a digital feedback signal from the analog-to-digital converter, the automatic gain control module including a first accumulator and a second accumulator that compare the digital feedback signal against a first and second threshold, respectively, and count a number of times that the digital feedback signal falls between the first and second threshold such that the automatic gain control module can adjust a gain of the variable gain amplifier dependent upon the number of times the digital feedback signal falls between the first and second threshold.

2. The SerDes channel of claim 1, wherein the first threshold is greater than the second threshold and wherein the first accumulator counts a number of times the digital feedback signal exceeds the first threshold over a predetermined period.

3. The SerDes channel of claim 2, wherein the second accumulator counts a number of times the digital feedback signal exceeds the second threshold.

4. The SerDes channel of claim 3, wherein the second accumulator counts the number of times the digital feedback signal exceeds the second threshold over the predetermined period.

5. The SerDes channel of claim 3, wherein the second accumulator counts the number of times the digital feedback signal exceeds the second threshold over a second predetermined period that is different from the predetermined period over which the first accumulator is counting the number of times the digital feedback signal exceeds the first threshold.

6. The SerDes channel of claim 2, wherein the predetermined period is based on at least one of a predetermined number of clock cycles, a predetermined number of symbol intervals, and a predetermined amount of time.

7. The SerDes channel of claim 1, wherein the automatic gain control module adjusts the gain of the variable gain amplifier to enable the analog-to-digital converter to utilize as much of its dynamic range without oversaturating the analog-to-digital converter.

8. The SerDes channel of claim 1, wherein the first threshold is approximately one decibel below a maximum input of the analog-to-digital converter and wherein the second threshold is at least one-and-a-half decibels below the maximum input of the analog-to-digital converter.

9. The SerDes channel of claim 1, wherein the digital feedback signal is received directly from a digital output of the analog-to-digital converter.

10. The SerDes channel of claim 1, further comprising at least one digital processing component that receives a digital output from the analog-to-digital converter and wherein the digital feedback signal is received from an output of the at least one digital processing component.

11. A mixed signal communication system that includes an analog signal and a digital signal, the mixed signal communication system comprising:
an analog-to-digital converter that receives an analog input signal and converts the analog input signal into the digital signal;
a variable gain amplifier connected to an input of the analog-to-digital converter via a switch that selectively connects and disconnects the analog-to-digital converter from the variable gain amplifier via control of a clock and data recovery circuit; and
an automatic gain control module in communication with the analog-to-digital converter and that receives a digital feedback signal that is directly obtained from the digital signal output by the analog-to-digital converter, the automatic gain control module comprising:
a first accumulator that counts a number of times that the digital feedback signal either exceeds or fails to exceed a first programmable threshold over a monitoring period, wherein the first programmable threshold defines an upper boundary of a preferred operating range for the analog-to-digital converter;
a second accumulator that counts a number of times that the digital feedback signal either exceeds or fails to exceed a second programmable threshold over the monitoring period, wherein the second programmable threshold defines a lower boundary of the preferred operating range for the analog-to-digital converter; and
a controller that adjusts a gain of the variable gain amplifier dependent upon feedback from the first and second accumulators.

12. The mixed signal communication system of claim 11, wherein the first accumulator creates a first absolute sum of the number of times that the digital feedback signal exceeds the first programmable threshold over the monitoring period and wherein the second accumulator creates a second absolute sum of the number of times that the digital feedback signal exceeds the second programmable threshold over the monitoring period.

13. The mixed signal communication system of claim 12, wherein the controller is configured to incrementally decrease the gain of the variable gain amplifier when the first absolute sum exceeds an upper programmable sum limit within the monitoring period.

14. The mixed signal communication system of claim 13, wherein the controller is configured to incrementally increase the gain of the variable gain amplifier when the second absolute sum fails to exceed a lower programmable sum limit within the monitoring period.

15. The mixed signal communication system of claim 11, wherein the analog-to-digital converter comprises at least a 6 bit analog-to-digital converter, wherein the variable gain amplifier is configured to be adjusted in at least 0.5 decibel increments, and wherein the automatic gain control module is configured to incrementally adjust the variable gain amplifier only after the monitoring period has ended.

16. The mixed signal communication system of claim 15, further comprising at least one adaptive loop and wherein the automatic gain control module is configured to limit a frequency with which the variable gain amplifier is adjusted so as to avoid changing a variable gain amplifier index and, therefore, avoid disturbing the at least one adaptive loop.

17. A method of operating a mixed signal communication system, comprising:
receiving an input analog signal at a variable gain amplifier;
using the variable gain amplifier to create an amplified analog signal;
providing the amplified analog signal to an analog-to-digital converter;
using the analog-to-digital converter to convert the amplified analog signal into a first digital signal;
receiving a digital feedback signal at an automatic gain control module, wherein the digital feedback signal corresponds to an output received directly from the analog-to-digital converter;
accumulating a first number of output samples in the digital feedback signal that exceed a first programmable threshold over a monitoring period, wherein the first programmable threshold defines an upper boundary of a preferred operating range for the analog-to-digital converter;
accumulating a second number of output samples in the digital feedback signal that fail to exceed a second programmable threshold over the monitoring period, wherein the second programmable threshold defines a lower boundary of the preferred operating range for the analog-to-digital converter; and
based on the accumulated first number and accumulated second number, controlling a gain of the variable gain amplifier to ensure that the analog-to-digital converter is operated in the preferred operating range.

18. The method of claim 17, wherein controlling the gain of the variable gain amplifier comprises incrementally decreasing the gain of the variable gain amplifier when the accumulated first number exceeds an upper programmable sum limit within the monitoring period.

19. The method of claim 17, wherein controlling the gain of the variable gain amplifier comprises incrementally increasing the gain of the variable gain amplifier when the accumulated second number fails to exceed the second programmable threshold over the monitoring period.

20. The method of claim 17, wherein the first programmable threshold and second programmable threshold are separated by a range corresponding approximately to a minimum increment that the variable gain amplifier can be adjusted.
